(19) United States
(12) Patent Application Publication
(10) Pub. No.: US 2024/0113216 A1
(43) Pub. Date: Apr. 4, 2024

(54) SEMICONDUCTOR DEVICE AND METHOD OF PRODUCING THEREOF

(71) Applicant: Infineon Technologies AG, Neubiberg (DE)

(72) Inventors: Yuliya Lisunova, Villach (AT); Andreas Frank Behrendt, Villach (AT); Carsten Schaeffer, Annenheim (AT); Simon Paul Sindermann, Mulheim an der Ruhr (DE); Adriana Mercedes Sanchez Lotero, Villach (AT); Silke Liebscher, Ehringhausen (DE)

(21) Appl. No.: 18/471,777

(22) Filed: Sep. 21, 2023

(30) Foreign Application Priority Data
Sep. 30, 2022 (DE) 102022210410.2

(51) Int. Cl. H01L 29/78; H01L 29/06; H01L 29/10; H01L 29/20; H01L 29/66

(52) U.S. Cl. CPC H01L 29/7811; H01L 29/0696; H01L 29/1095; H01L 29/2003; H01L 29/66068; H01L 29/66712

(57) ABSTRACT

Disclosed herein is a power semiconductor device including a semiconductor body, a first load terminal, a second load terminal, an active region, an edge termination region, and a thin film layer that includes a bulk material and a laminar filler compound. Furthermore, a method of producing such a power semiconductor device is described herein, the method including: providing a thin film including a mixture of a bulk material component and a laminar filler compound onto a surface of at least parts of the edge termination region and/or over at least parts of the first load terminal; and curing the obtained mixture of the bulk material and laminar filler compound to generate a thin-film layer that includes a bulk material and a laminar filler compound.

### TECHNICAL FIELD

The present disclosure relates to the field of semiconductor devices and, in particular, to power semiconductor devices comprising a specific layer structure at the edge termination region, and to methods of producing thereof.

### BACKGROUND

Semiconductor devices in general and, in particular, high-power modules like IGBT, diodes and MOSFETs, are sensitive to harsh environmental conditions. The packaging applied sometimes do not shield the power electronics from environmental influences. Increased humidity level and temperature variation can lead to drastic changes in the material properties and blocking behavior of the semiconductor devices.

Therefore, there is a need of improving external stress resistance and lifetime characteristics of semiconductor devices.

### SUMMARY

Disclosed herein is a power semiconductor device, comprising a semiconductor body (the body comprising a first surface and a second surface), a first load terminal arranged on the first surface and a second load terminal arranged on the second surface, an active region comprising at least one semiconductor cell for conducting a load current between the first load terminal and the second load terminal, an edge termination region between the active region and a chip edge. The chip edge may border the first surface and the second surface of the semiconductor body in the power semiconductor device. The semiconductor device further comprises a thin film layer provided over at least parts of the edge termination region and/or over at least parts of the first load terminal, wherein the thin film layer comprises a bulk material and a laminar filler compound. The thin film layer, thus, shields the semiconductor device structures covered by it from the environment to isolate the semiconductor device structures from external stresses. The provision of the thin film layer over at least parts of the edge termination region and/or over at least parts of the first load terminal of the devices isolates at least those parts of the edge termination region and of the first load terminal being in direct contact therewith or being covered therewith. A direct contact is not necessary if other structures or layers are provided between the edge termination region and/or the first load terminal and the thin film layer. In this case the thin film is positioned above the respective structures of the semiconductor device. Thus, the thin film as described herein may improve external stress resistance and lifetime characteristics of the semiconductor device provided therewith.

Furthermore, a method of producing such a power semiconductor device is described herein, wherein the method at least comprises providing a thin film comprising a mixture of a bulk material component and a laminar filler compound onto the surface of at least parts of the edge termination region and/or over at least parts of the first load terminal and curing the bulk material compound, thereby generating a thin-film layer comprising a bulk material and a laminar filler compound. The thus generated thin film layer may be used to isolate at least those parts of the edge termination region and the first load terminal being brought into direct contact therewith or being covered by the thin-film layer above these semiconductor device structures, in case additional layers or structures are provided between them. The thin film layer may improve external stress resistance and lifetime characteristics of the semiconductor devices provided therewith.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a cross sectional view of an embodiment of a power semiconductor device comprising a semiconductor structure thereof provided with a protective thin film layer as described herein.

FIG. 2 illustrates a section of a horizontal projection of a power semiconductor device in accordance with one or more embodiments.

FIG. 3 illustrates a partial view of the power semiconductor device as shown in FIG. 1.

FIG. 4 illustrates a cross sectional view of a further embodiment of a power semiconductor device with a silicon nitride film between the semiconductor part and the protective thin film layer.

FIG. 5 illustrates a schema of an embodiment of the method described herein.

### DETAILED DESCRIPTION

The examples described herein provide a power semiconductor device (in the following description also mentioned as semiconductor device) comprising a thin film layer provided as a protective thin film over at least parts of the edge termination region and/or over at least parts of the first load terminal of the semiconductor device. The semiconductor device may involve semiconductor chips having a vertical structure. That is to say that a semiconductor chip of a vertical semiconductor device (e.g. being the vertical semiconductor device) may be fabricated in such a way that electric currents are flowing in a direction perpendicular to the main surfaces of the semiconductor chip. A semiconductor chip having a vertical structure usually has first and second load terminals on its two main surfaces, that is to say a first load terminal on its top side (herein the first surface) and a second load terminal on its bottom side (herein the second surface). While the description exemplifies the technical solution based on vertical semiconductor devices, it similarly may be used in a horizontal semiconductor device. In such a semiconductor device, the electrical currents are flowing in a direction parallel to the main surfaces of the semiconductor chip and the first and second load terminals are usually placed on the front main surface of the semiconductor chip.

The thin film layer may be provided as passivation layer above the surface of structures or regions of the semiconductor devices. In this specification, the term “above” does mean that a layer is applied on the surface of these device structures or regions or via one or more other structures or layers. Thereby the thin film layer may be directly on the device structures or regions or may extend directly onto another layer or element. Intervening layers or elements may also be present. In contrast, when a layer or an element is referred to as being “directly on” or extending “directly onto” another layer or element, there are no intervening layers or elements present.

The semiconductor device, such as a high voltage semiconductor device (e.g. a semiconductor chip) may, for example, be configured as an IGBT (Insulated Gate Bipolar Transistor), a FET (Field Effect Transistor), in particular a MOSFET (Metal Oxide Semiconductor FET), a JFET (Junction Gate FET), a thyristor, specifically a GTO (Gate Turn-Off) thyristor, a BJT (Bipolar Junction Transistor), an HEMT (High Electron Mobility Transistor), or a diode. By way of example, a source electrode and a gate electrode of, e.g., a FET or MOSFET may be situated on the top side surface, while the drain electrode of the FET or MOSFET may be arranged on the bottom side surface.

The semiconductor body may comprise a semiconductor substrate, e.g. a processed wafer or a wafer with epitaxial layers comprising several device structures on or over a surface of the wafer. The semiconductor substrate may comprise or be of a semiconductor material such as, e.g., Si, SiC, SiGe, GaAs, GaN, AlGaN, InGaAs, InAlAs, etc. For instance, the semiconductor substrate may be a wafer or a chip comprising an active region. The active region may comprise at least one semiconductor cell for conducting a load current between the first load terminal and the second load terminal arranged on the first and second surfaces thereof, respectively. For instance, the first and second load terminals may be formed by a high voltage electrically conductive structure, which is, e.g., made of metal. All kinds of metal or metal alloy may be used for the load terminals, though in many cases the metal may comprise or be of aluminum or copper or an alloy of aluminum or copper. Examples of the load terminals are set out further below. It is to be noted that load terminals may be located relatively close to the anode of the active region so as to be subjected to high electrical fields during operation of the semiconductor device. The load terminals may be configured to be applied with a high voltage of equal to or greater than 0.6 kV, 1 kV, 2 kV, 3 kV or 4 kV or 5 kV or 6 kV or 6.5 kV during operation. This voltage may be applied between a first load terminal (e.g. anode, source, emitter or another electrically conductive structure connected with the first load terminal) and a second load terminal of the power semiconductor device (e.g. a cathode, drain or collector at the bottom side of the semiconductor body) arranged, e.g., at a surface of the semiconductor body opposite to the surface of the semiconductor body where the first load terminal is provided.

An edge termination region may be between the active region and a chip edge of the semiconductor body, e. g. near the first surface. For example, the edge termination region may be arranged within the semiconductor body in proximity to the first surface or adjoining the first surface. The chip edge may be a lateral border of the semiconductor body. The chip edge may be cutting edge resulting from separating the semiconductor body from a wafer during manufacture. The chip edge may indicate the border between the first surface and the second surface of the semiconductor body. In some examples, the chip edge may also define the boarder to a neighboring chip on a wafer substrate. Two or more such chips may be placed on a single wafer, and each may have chip edges related to its neighboring chips. The edge termination region, thus, helps to separate the chips integrated on one wafer. Moreover, the edge termination region can be used to facilitate the separation of the individual chips within the edge termination region when slicing the individual chips from a wafer with a number of chips during manufacturing of the semiconductor device.

A thin film layer may be provided over at least parts of the edge termination region and/or over at least parts of the first load terminal as a protective layer for the semiconductor structures covered therewith. For instance, the thin film layer may be arranged in proximity to the edge termination region at the first surface of the semiconductor body. The thin film layer may comprise a bulk material and a laminar filler compound. Thus, the thin film layer facilitates improving the external stress resistance and lifetime characteristics of the semiconductor devices provided therewith. The improvement is assumed to be achieved by a structured integration or admixture of the filler compound within the bulk material (i.e., the bulk material functions as matrix) during the preparation of the thin film layer. The specific structuring of the thin film layer may lead to changes in the material properties and the blocking behavior of the semiconductor device, e.g., in environments with high humidity and other external stresses.

More particularly, the thin film layer described herein may be used as a new type of passivation material of high gas and thermal barrier properties. Thus, the introduction of a laminar filler compound in a thin film layer mainly comprised of a bulk material allows a cost-effective manufacturing method of passivation material in micro-scale format. As semiconductor devices are in micro-scale format, thin film means in the context of the description herein a layer thickness of about less than 50 μm, less than about 40 μm, less than about 30 μm, e.g., between about 6 and 20 μm. The thickness of the thin film layer provided as a passivation layer mainly depends on the voltage class of the semiconductor device. An increased thickness may lead to an increase of the dielectric constant and an increase in remnant polarization. An increased dielectric constant may result in an improved robustness of the semiconductor device. It has been shown in experiments that the integrated laminar filler compound can affect rheological, thermal, and dielectric properties of the polymer matrix in the micro-scale thin films. This may result in an improved robustness quality as a passivation layer for semiconductor devices.

In the context of the present application, laminar filler compound means that the filler compound may be arranged in a two-dimensional layered structure within the bulk material matrix. Therefore, the laminar filler compound may substantially be constituted of particles with a two-dimensional planar orientation, such as flakes or the like. The two-dimensional structured filler compound may be as thin as about a few atomic layers only, for example, having an overall thickness of less than about 1 nm and having a very high aspect ratio. This allows that two or more filler compounds may be arranged in a stacked structure within the bulk material matrix of the thin film. Thus, a few weight percent load of layered laminar filler compound may create a high surface area interaction with the bulk material matrix. The laminar filler compound may, thus, form a three-dimensional network of integrated filler compounds blocking the direct way for any gaseous compounds through the thin film. The laminar filler compounds are substantially arranged parallel to the elongation of the thin film, that means perpendicular to the diffusion pathway of the gaseous compounds. This increases the blocking action for the gaseous compounds within the thin film layer and may be the reason for the improved characteristics of the thin film layers described herein and their use as protective layers in semiconductor devices. The diffusion of the gaseous compounds may be at least slowed down or may be blocked at all.

In some examples, the laminar filler compound may be a dielectric material. Thus, the integrated laminar filler compound can affect dielectric properties of the polymer matrix in the thin films. This may result in improved dielectric properties of the passivation layer for semiconductor devices.

In some examples, the semiconductor device may comprise one or more semiconductor and/or oxide structures. Exemplified semiconductor structures may be doped zones or trenches included within the semiconductor (e.g., Si, or SiC) substrate. Exemplified oxide structures may be silicon oxide areas or layers, e.g., an electrically insulating buffer layer. The active region of the semiconductor device may comprise, for instance, a semiconductor layer or silicon nitride layer having a nitride surface in at least parts thereof. Two or more of these additional layers may be integrated into the semiconductor body of the semiconductor device depending on the functionality of the semiconductor device. The semiconductor layer or the silicon nitride layer may be part of a layer stack provided over an active region topography for passivation reasons, for example.

According to some examples, the first and second load terminals may comprise one or more metal layers such as, for instance, the active metal electrode (anode and cathode or, respectively, emitter and collector, or source and drain), metallic field plates and peripheral conductive structures. These metal structures may all be made of the same metal, e.g., aluminum or copper or an alloy of these metals (e.g., aluminum copper alloy, optionally having a silicon content). The portion of a semiconductor device, which includes the active metal electrode and/or the metallic field plates and/or the peripheral conductive structures may represent an edge termination region of the semiconductor device which surrounds the active zone of the semiconductor device. In the examples described herein, this portion is at least partly protected by the application of the thin film layer as described herein.

Therefore, according to some examples, the thin film layer may be provided over at least parts of the edge termination structure and first load terminal as a passivation layer of regions near the chip edge. At least some parts of these structures or any of these structures (e.g., the edge termination structure) may, thus, be covered by the thin film layer. As explained above, the passivation layer provided in these portions of the semiconductor device provide a high gas and thermal barrier. Hence, at least the covered parts are protected from external stresses and, therefore, may improve the external stress resistance and lifetime characteristics of the semiconductor device.

The thin film layer may comprise an UV and/or light curable resin. Resins generally are substances that are produced chemically and used to make plastics but can also be of natural sources. A resin-based passivation layer at the edge termination can be used to isolate the semiconductor device from external stresses. Exemplified resins are curable, for example, by UV light or light in the visible or IR region of the spectrum. In the photo lithographic field, UV curable resins are used as photoresists. They usually can easily be spin coated, thereby forming a thin film on or onto a workpiece and can then be cured by interaction with the UV or other light irradiation. Exemplified resins are photopolymers such as photoimides.

The bulk material of the thin film layer may comprise an imide-based, ethylene-based, or propylene-based polymer, or a combination thereof. Such polymers are known for their high chemical and thermal robustness and may be dielectrically inert. A polymer resin may be generated by spin-coating a mixture of a polymer monomer together with the laminar filler material, and optionally other additives, if needed, and curing the mixture to a final thickness of about a few micrometers. Exemplified thicknesses are at least about 5 μm and at most about 50 μm, for example 6 to 20 μm, or about 10 μm. In some examples, the polymer-based bulk material is manufactured from monomers of a photopolymer which do not need a separate UV or light curing component. In other examples, e.g., if the monomers are not photopolymers or if the curing reaction shall be accelerated, a curing aid compound may be comprised in the mixture. Exemplified UV curable resins are photoimides, e.g., amidocarbon acids with crosslinkable functional ester groups in the monomers, which can be activated by UV exposure. The photoimides may include rigid and flexible polyimides. Flexible polyimides can be obtained by the use of semi-flexible or flexible monomers, e.g., ether-based diamine monomers as precursor which provide some flexibility to the polymer chains by the ether groups in the backbone, for instance.

In case of the use of curable resins, a photocuring reaction (e.g., using UV exposure) such as a polycondensation of the amidocarbon acids may be initiated to generate the thin film polymer layer (comprising amide chains) as a passivation layer for protecting the covered semiconductor device structures (e.g., within the edge termination region). Exemplified curing aids can be additives assisting the photocuring reaction of the photoimide monomers. The photocuring reaction may take place under UV exposure. UV exposure can be followed by a curing act at about 350 to 450° C. to remove solvents and to solidify the polymer matrix.

In some examples, laminar filler compounds may provide the thin film layer with a laminar structure in which the laminar filler compound is oriented substantially parallel to a surface of the semiconductor device surface, e.g., the first main surface of the semiconductor body. Substantially parallel means in the context described herein that most of the laminar filler compounds are oriented such that the diffusion pathway perpendicular to the semiconductor surface is blocked for gaseous compounds by a complex network structure of the laminar filler compounds. Two or more integrated sheet layers of filler compounds may be integrated into the thin film layer after the curing of the bulk material matrix.

The integration of the laminar filler compound into the bulk material thin film layer, e.g., the imide-based resin layer, further may improve the mechanical, morphological, thermal, and dielectric properties of the thin film layer (e.g., polyimide layer). The laminar filler compounds not only have a specific two-dimensional shape as explained before but can be selected from specific inorganic fillers. Examples of inorganic fillers may be layered silicates such as clays, or nanoclays, e.g., smectite-like clay minerals or montmorillonite clay minerals. Some examples are alumino silicates having a chemical formula of (OH)₄Si₈Al₄O₂₀·nH₂O, for instance. Such clays are available as powder material with densities of about 200-500 kg/m³, thicknesses of a few nanometers, e.g., about 1 nm, length of up to about 40 μm, e.g., about 20 μm. Suitable clays are selected to improve the modulus of the mixture, to increase the barrier properties, to enhance the chemical resistance, to improve the rheology, and/or to increase the heat deflection temperature, for example.

The content of the laminar filler compound in the thin film layer may, for instance, be at least 0.5 wt.-% and at most about 5 wt.-%. Exemplified loads may be 0.5 wt.-%, 1 wt.-%, 2 wt.-%, from 3 up to 5 wt.-%, for instance.

In some examples the thin film layer may comprise a nanoclay photoimide composite resin as a passivation layer. The, thus, provided passivation layer provides high gas and thermal barrier properties to the thin film layer to improve the humidity resistance and lifetime characteristic of, e.g., high power semiconductor devices, at the edge termination region, for instance. The reason may be that the bonding of nanoclay materials to the polymer structure limits the adsorption of water, thus reducing hydrolysis of the nanoclay photoimide composite. An explanation is that the nanoclay may form bonds to polar groups of the photoimide or polymer through hydrogen bonding (hydrolysis), thus reducing the tendency of absorbing water molecules from the environment. Thus, the reduction of the hydrolysis reaction reduces the decomposition of the polymer in humid environments, thus increasing the lifetime of the semiconductor devices.

The reduction of absorbing water molecules in the nanoclay photoimide composite may be improved using surfactant modified nanoclay compounds. Examples thereof include surfactant modified clays having a hydrophobic-modified surface. The use of laminar filler compounds having a hydrophobic-modified surface allows a more uniform dispersion of the filler component in the bulk material matrix via mixing and then curing the obtained mixture to generate a thin film layer. When using the surfactant modified clays, cations may react with the polymer matrix, initiate the polymerization of the monomers, and improve the strength of the interface between the inorganic filler component (i.e., the laminar filler compound) and the polymer matrix. It is assumed that this forced and improved bonding between the clay and polymer matrix may minimize dangling bonds that, otherwise, are likely to absorb water molecules. Exemplified surfactants include silane coupling agents (e.g., aminopropyl triethoxsilane), amines (e.g., octadecylamine, dimethyl dialkyl (C14-C18) amine), and ammonium compounds (e.g., trimethyl stearyl ammonium), to name a few examples only.

The surfactants are contained in the mixture in an amount of up to 50 wt.-%. Amines and ammonium components may be used in an amount of about 10 to 50 wt.-%, for example. More particular, amounts of about 15-35 wt.-% for octadecylamine, about 25-30 wt.-% for trimethyl stearyl ammonium, and about 35-45 wt.-% for dimethyl dialkyl amine may be mentioned. The content of the silane surfactant such as aminopropyltriethoxysilane in the mixture may be less than 10 wt.-%, for example, about 0.5 to 5 wt. %.

The mixture for manufacturing the laminar filler bulk material composite may include further additives or solvents if required for the processability during the manufacturing of the thin film layer. The thin film layer may be produced in situ on the previously obtained semiconductor work piece to be protected by such a passivation layer.

Further examples described herein relate to a method of producing a semiconductor device which at least comprises a semiconductor body, a first and second load terminal, an active region, and an edge termination region as defined before. The method at least comprises providing a thin film comprising a mixture of a bulk material component and a laminar filler compound onto the surface of at least parts of the edge termination region and/or over at least parts of the first load terminal and curing the bulk material component. The mixture may be applied onto the workpiece by a suitable coating process such as spin coating, for example. The coating generates a thin-film layer comprising at least a bulk material and a laminar filler compound. After curing of the bulk material in admixture with the laminar filler compound in form of a thin film, a thin film layer comprising a bulk material and a laminar filler compound is obtained. In some examples, the bulk material component may be a UV curable resin monomer such as a photoimide and the curing is a photocuring reaction. Exemplified UV curable resin monomers and laminar filler compounds are described with regard to the semiconductor device herein before.

In some examples of the method, the mixture comprising at least the bulk material component and the laminar filler compound may further comprise a curing aid compound. The curing aid may facilitate the UV or light curing reaction. In case photoresists are used, external curing aids are not necessarily needed as the reactive sites may be placed within the monomer components.

In some examples of the method, the bulk material and the laminar filler compound are configured to form an imide-based polymer composite thin film as a passivation layer. In those methods, the bulk material is mainly based on a monomer component to form an imide-based polymer composite thin film as a passivation layer to protect the covered parts of the edge termination region and of the first load terminal from external stresses. The method may also be configured such that the curing may generate a thin film layer comprising a nanoclay photoimide composite resin. The thus obtained composite resin may be used as passivation layer, e.g., in the edge termination region of a semiconductor device as described herein before.

In order to improve the coating method and to realize a predetermined thickness of the thin film layer, suitable additives or solvents may be used together with the bulk material component and the laminar filler compound. Exemplified additives are surface modifiers and dispersion aids. Surface modifiers may, for example, be surfactants for modifying the bulk material and were described herein before such as silane coupling agents. The additives may be miscible in the bulk material. If needed, e.g., as viscosity modifier, suitable solvents may be used in the coating mixture. Examples are N-methyl-pyrrolidone (NMP), N,N-dimethyl acetamide (DMAc), dimethyl formamide (DMF), dimethyl sulfoxide (DMSO), m-cresol, pyridine (PY), dioxane, tetrahydrofuran (THF), methanol (ML), ethanol (EL), propylene carbonate (PC), acetyl tributyl citrate (ATBC), 4-tert-butyl catechol (TBC), triethyl phosphate (TEP), and γ-butyrolactone (GBL). Mixtures of these solvents or with other solvents may be used as well. The content of the solvent may be up to 30 wt.-%, up to 25 wt.-%, up to 15 wt.-%, and, e.g., about 5 to 15 wt.-%.

For example, the power semiconductor device may be implemented on a single semiconductor chip, e.g., exhibiting a stripe cell configuration (or a cellular/needle cell configuration) and can be configured to be employed as a power component in a low-, medium- and/or high voltage application.

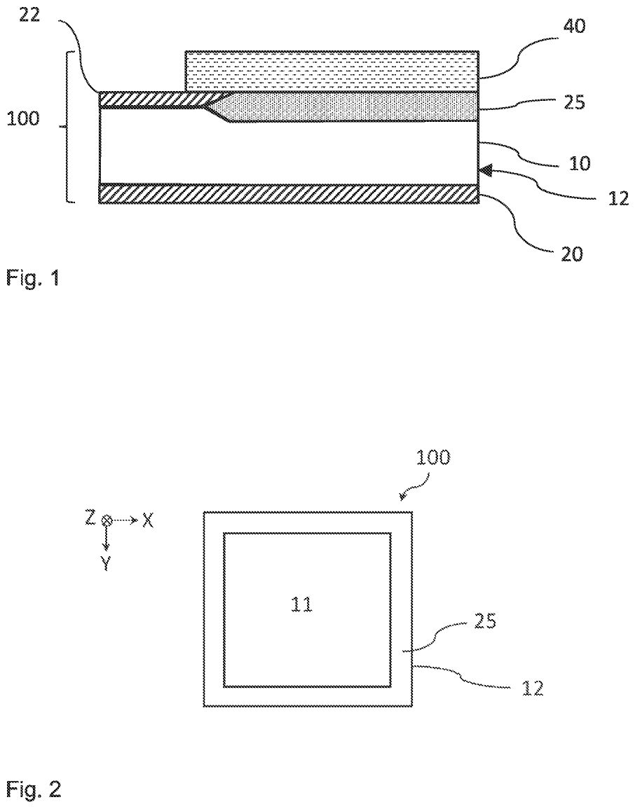

One embodiment of a power semiconductor device (100) is shown in FIG. 1 in a cross-sectional view. Shown is the part of an edge termination region, herein referred to as 25. The semiconductor device 100 comprises a semiconductor body 10 with a cathode as second load terminal 20 at the bottom surface and a first load terminal 22 at the top surface of the semiconductor body 10. Between the lateral chip edge 12 and the first load terminal 22, an edge termination region 25 is placed. Specific device structures of the semiconductor body 10 and of the first and second load terminals 20 and 22 have been omitted for clarity reasons in this drawing. A thin film layer 40 is provided in the region of the edge termination region 25 and parts of the first load terminal 22, thus protecting at least the edge termination region from external stresses.

Corresponding to FIG. 1, FIG. 2 illustrates a section of a horizontal projection of a power semiconductor device 100 in accordance with one or more embodiments. The power semiconductor device 100 comprises a semiconductor body 10 coupled to a first load terminal 22 and a second load terminal 20. An active region 11 is configured to conduct a load current between the first load terminal 22 and the second load terminal 20.

As illustrated, the semiconductor body 10 may be sandwiched between the first load terminal 22 and the second load terminal 20. Hence, the power semiconductor device 100 may exhibit a vertical configuration, according to which the load current follows a path substantially in parallel to the vertical direction Z. The active region 11 may be confined by a border where the active region 11 transitions into the edge termination region 25, which is in turn terminated by the chip edge 12.

Herein, the terms active region and edge termination region are used in a technical context the skilled person typically associates with these terms. Accordingly, the active region's purpose is primarily to ensure load current conduction, whereas the edge termination region 25 is configured to reliably terminate the active region 11, e.g. in terms of courses of the electric field during conduction state and during blocking state.

The thin film layer 25 of this embodiment has been generated by mixing a photoimide (polyamidocarbon acid obtained from precursors pyromellitic dianhydride and oxydianiline), a surface modified nanoclay (montmorillonite clay with length smaller than 20 mm, thickness of about 1 nm, and density of about 200-500 kg/m 3) modified with aminopropyl triethoxysilane and additional additives, if any, and NMP as solvent. Three surface modified nanoclay compositions were tested. The first one contains 15-35 wt.-% octadeylamine and 0.5-5 wt.-% aminopropyl triethoxy silane. The second one contains 25-30 wt.-% trimethyl stearyl ammonium. The third one contains 35-45 wt.-% dimethyl dialkyl amine with alkyl rests having 14 to 18 C atoms. The viscosity of the photoimide used was between about 5,000 and 8,000 mPa*s, e.g., 5,500 mPa*s or 7,500 mPa*s. The loads of clay component in the tested mixtures were 0.5 wt.-%, 2 wt.-%, and 5 wt.-%, while other loads may be suitable as well. The litho transparency of the obtained composite after curing generally decreases with the weight load of clay so that the weight load should be determined based on the desired properties.

The amount of solvent has been adjusted such that the viscosity of the mixture is sufficient for a spin coating of the mixture in a desired thickness. In some examples 15 wt.-% of solvent has been used for mixing 80 wt.-% photoimide and 5 wt.-% nanoclay. The resultant viscosity range was about 1,500-3,000 mPa*s.

The mixture was spin coated onto the surface of the workpiece in the edge termination region and part of the first load terminal in the form of a suspension of the nanoclay material in the photoimide solution. After application by spin coating, the photoimide was cured by UV irradiation so that a photoimide matrix with integrated nanoclay was obtained, also called nanoclay-photoimide composite. Different thicknesses between 3 and 20 μm were prepared, e.g. 4 μm, 6 μm, 11 μm, 16 μm. It was observed that the silane modified nanoclay has an improved sedimentation in the solvent NMP and provides a sufficient adhesion to silicon and silicon nitride. The composite obtained is lithographically transparent so that it can be used as a passivation layer for power semiconductor devices as described herein.

In other embodiments, photoimides with semi-flexible or rigid diamine monomers were used, e.g., aromatic diamines such as para phenylene diamine, for instance. Different aromatic tetracarbon acids or acid anhydrides are used as precursors for the photoimides instead of pyromellitic dianhydride monomer.

The resultant nanoclay-photoimide composite thin film layers obtained in the embodiments described above were tested in a bulk and in a device configuration as a passivation layer. The uniformity of the bulk composite could, for example, be monitored by scanning electron microscope (SEM), X-ray diffraction (XRD), and thermogravimetric (TGA) analysis. The compatibility of the nanoclay-photoimide composite with front-end-of-line technology (FEOL) were, for example, proven with diodes manufacturing. Similar test results of the composite thin films were obtained as imide-based thin film layers without nanoclay component. The compatibilities of nanoclay-photoimide composites with back-end-of line (BEOL) were proven in modules with HV-H3TRB and HTRB tests. No abnormalities were observed in these tests.

The humidity uptake effect was analyzed in several independent tests in a bulk and in device configuration as follows:

Gravimetric analysis of bulk material: the water absorption of nanoclay-photoimide composite under saturated conditions were measured and referenced to standard photoimide without clay (samples 2 cm in diameter and 0.5 cm in thickness);

Pull-shear stress measurements at wafer level: The adhesion of the spin-coated nanoclay-photoimide composite thin film to the underlying substrate within shear force measurements was conducted with and without water adsorption stress (patterned wafers with photoimide and nanoclay-photoimide composite, respectively, were emerged in water for 180 days); and

WL-HTRB, HV-H3TRB and HTRB tests.

The gravimetric analysis demonstrated lower humidity uptake of nanoclay-photoimide composite in comparison to photoimide alone (5 times less humidity uptake compared to photoimide alone, tested in a bulk).

The pull-shear stress tests showed high bonding strength of nanoclay-photoimide composite to both tested substrates: silicon and silicon nitride. The adhesion is comparable to photoimide resists without nanoclay content. Moreover, 180 days of water adsorption stress did not change any pull-shear response in the test samples.

The dielectric stability of the nanoclay-photoimide composite were monitored in several tests under voltage load within the range of 1700 V to about 2000 V: FCT, WL-HTRB for 96 hours and HTRB tests at 175C KE1070 gel. FCT shows any abnormalities for nanoclay-photoimide composite and measured electrical parameters are within the device specification. Yb yield is comparable to photoimide alone.

The dielectric compatibility of the nanoclay-photoimide composites (0.5%, 2% and 5% clay load) was proven within WL-HTRB tests. The nanoclay-photoimide composite specimens are more robust within WL-HTRB tests in comparison to photoimide samples without any clay content.

HTRB tests had been performed at harsh conditions with ion response sensitive KE1070 gel at 175° C. Test results are comparable to photoimide alone. No abnormalities had been observed.

Hence, the obtained semiconductor devices with nanoclay-photoimide composite as passivation layer above the edge termination region and parts of the first load terminal as has been described herein before showed the compatibility of composite materials in semiconductor power device electronics and build-up modules. The compatibility could be proven in device manufacturing and device performance. No abnormalities were observed within electrical tests. The power semiconductor devices showed an improved humidity robustness for the nanoclay-photoimide composites at micro-scale. Moreover, the dielectric robustness provided by the nanoclay-photoimide composite thin films at micro-scale, especially, at wafer level tests and module configurations at harsh environmental conditions could be demonstrated. Therefore, the power semiconductor devices with a specifically structured thin film layer comprising a bulk material and a laminar filler compound showed improved external stress resistance and lifetime characteristics of the power semiconductor devices.

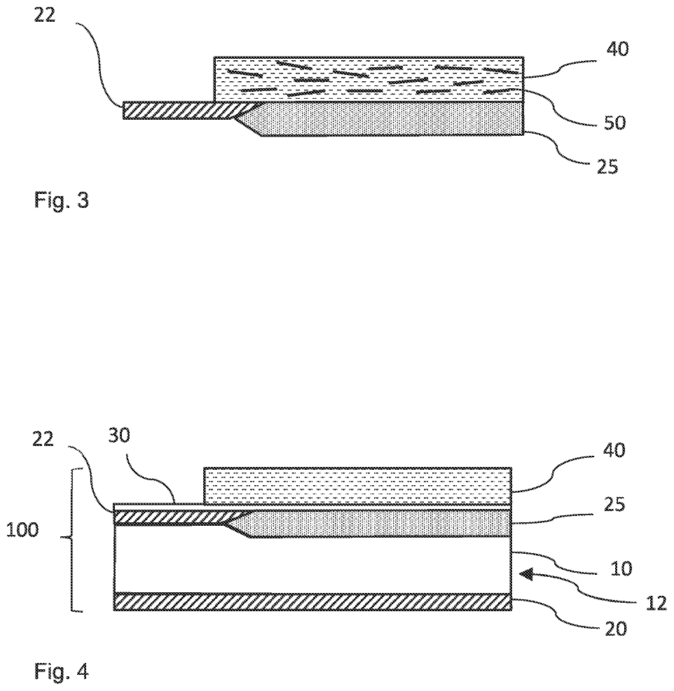

In FIG. 3 a partial view of the power semiconductor device as shown in FIG. 1 has been illustrated. In this partial view, the specific structure of composite material in the thin film layer 40 has been shown in greater detail. The thin film 40 is provided at least partly over the first load terminal 22 and the edge termination region 25. Within the thin film, the laminar filler compound 50 (e.g., a nanoclay as layered silicate) is arranged substantially parallel to the surface of the semiconductor device. Two or more layers of nanoclay compounds 50 are arranged such that the diffusion pathway of gaseous compounds is blocked, or the diffusion time is prolonged as the layers of nanoclays hinder the gaseous compound at a free diffusion pathway.

FIG. 4 illustrates a cross sectional view of a further embodiment of a power semiconductor device 100 with a silicon nitride film 30 between the semiconductor part (i.e., the first load terminal 22 and the edge termination region 25) and the thin film layer 40. This embodiment shows that additional layers may be arranged on the semiconductor body before the protective thin film layer 40 is applied thereon to protect the underlying structures such as the edge termination region 25.

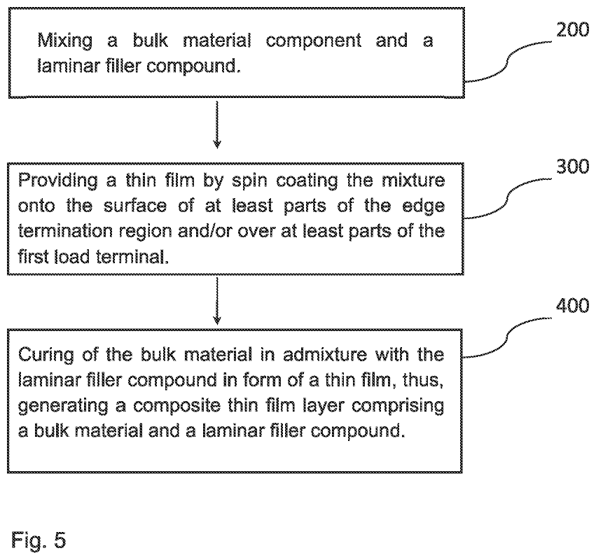

FIG. 5 shows an embodiment of a method for manufacturing a method of producing a semiconductor device as defined before which at least comprises the following acts/steps:

Mixing a bulk material component and a laminar filler compound (act 200);

Providing a thin film by spin coating the mixture onto the surface of at least parts of the edge termination region and/or over at least parts of the first load terminal (act 300); and

Curing of the bulk material in admixture with the laminar filler compound in form of a thin film, thus, generating a composite thin film layer comprising a bulk material and a laminar filler compound (act 400).

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A power semiconductor device, comprising:
a semiconductor body comprising a first surface and a second surface;
a first load terminal arranged on the first surface;
a second load terminal arranged on the second surface;
an active region comprising at least one semiconductor cell configured to conduct a load current between the first load terminal and the second load terminal;
an edge termination region between the active region and a chip edge; and
a thin film layer over at least parts of the edge termination region and/or over at least parts of the first load terminal,
wherein the thin film layer comprises a bulk material and a laminar filler compound.

2. The power semiconductor device of claim 1, wherein the first load terminal and the second load terminal both comprise one or more metal layers

3. The power semiconductor device of claim 1, wherein the thin film layer is over parts of the edge termination structure and the first load terminal as a passivation layer.

4. The power semiconductor device of claim 1, wherein the bulk material of the thin film layer comprises an UV and/or light curable resin.

5. The power semiconductor device of claim 1, wherein the bulk material of the thin film layer comprises an imide-based, ethylene-based, propylene-based polymer, or a combination thereof.

6. The power semiconductor device of claim 1, wherein the laminar filler compound of the thin film layer has a hydrophobic-modified surface.

7. The power semiconductor device of claim 1, wherein the thin film layer comprises the laminar filler compound in a laminar structure in which the laminar filler compound is oriented substantially parallel to a surface of the power semiconductor device.

8. The power semiconductor device of claim 1, wherein the laminar filler compound of the thin film layer comprises a layered silicate.

9. The power semiconductor device of claim 1, wherein the content of the laminar filler compound in the thin film layer is at least 0.5 wt.-% and at most 5 wt.-%.

10. The power semiconductor device of claim 1, wherein the thin-film layer comprises a nanoclay photoimide composite resin as a passivation layer.

11. A method of producing a power semiconductor device, wherein the power semiconductor device comprises a semiconductor body comprising a first surface and a second surface, a first load terminal arranged on the first surface, a second load terminal arranged on the second surface, an active region comprising at least one semiconductor cell configured to conduct a load current between the first load terminal and the second load terminal, and an edge termination region between the active region and a chip edge, the method comprising:
providing a thin film comprising a mixture of a bulk material component and a laminar filler compound onto a surface of at least parts of the edge termination region and/or over at least parts of the first load terminal; and
curing the bulk material component of the thin film layer to generate a thin-film layer comprising a bulk material and a laminar filler compound.

12. The method of claim 11, wherein the bulk material component is a UV curable resin monomer and the curing is a photocuring reaction.

13. The method of claim 11, wherein the mixture further comprises a curing aid compound.

14. The method of claim 11, wherein the bulk material and the laminar filler compound are configured to form an imide-based polymer composite thin film as a passivation layer.

15. The method of claim 11, wherein the curing generates a thin film layer comprising a nanoclay photoimide composite resin.
